(19) United States
(12) Patent Application Publication
(10) Pub. No.: US 2026/0323908 A1
(43) Pub. Date: Oct. 15, 2026

(54) SIDEWALL EPI-DEFINED CHANNEL FOR 4F2 DRAM

(71) Applicant: Applied Materials, Inc., Santa Clara, CA (US)

(72) Inventors: Fredrick David FISHBURN, Belmont, CA (US); Zhijun CHEN, San Jose, CA (US); Raghuveer S. MAKALA, Campbell, CA (US)

(73) Assignee: Applied Materials, Inc., Santa Clara, CA (US)

(21) Appl. No.: 19/174,918

(22) Filed: Apr. 10, 2025

(51) Int. Cl. H10B 12/00

(52) U.S. Cl. CPC H10B 12/05; H10B 12/315

(57) ABSTRACT

Instead of etching a very narrow trench in a 4F² DRAM process, the trench width can be increased to reduce tapering and roughness. A sacrificial layer may then be epitaxially grown on the trench sidewalls, followed by a layer of epitaxial silicon for the channel. The back gate oxide and metal may then be formed within the trench. The hard mask used to define the silicon fins may be removed to exactly expose the silicon fins for a self-aligned removal process. These fins can then be removed to expose the sacrificial layer, which may also be removed to expose the silicon channel. A relatively thick portion of the sacrificial layer formed at the bottom of the trenches may remain throughout the front side processing to be later used as a stop layer when removing the bulk of the underlying substrate during backside processing.

### TECHNICAL FIELD

This disclosure generally describes designs for advanced memory devices, such as 4F² dynamic random-access memory (DRAM) arrays. More specifically, this disclosure describes DRAM manufacturing techniques that define channel widths by controlled sidewall growth.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries. Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density.

### BRIEF SUMMARY

In some embodiments, a method of forming a portion of a DRAM structure may include forming a trench in a silicon layer between two silicon fins; forming a sacrificial layer on sidewalls of the trench between the two silicon fins; and forming a silicon channel layer on the sidewalls of the trench over the sacrificial layer.

In some embodiments, a method of forming a portion of a DRAM structure may include receiving a semiconductor structure that may include a silicon fin underneath a hard mask; a sacrificial layer on a sidewall of the silicon fin; a silicon channel layer on the sacrificial layer; and a gate oxide on the silicon channel layer. The method may also include removing the hard mask from above the silicon fin; removing the silicon fin to expose the sacrificial layer; and removing the sacrificial layer to expose a side of the silicon channel layer that is opposite the gate oxide.

In some embodiments, a method of forming a portion of a DRAM structure may include receiving a semiconductor structure that may include capacitors for DRAM cells on a top side of the silicon structure; back gate regions for the DRAM cells underneath the capacitors in the silicon structure, where the back gate regions may include a sacrificial layers beneath the back gate regions; and a substrate on a bottom of the silicon structure and beneath the back gate region. The method may also include removing a portion of the substrate beneath the sacrificial layers, wherein the sacrificial layers act as stop layers for a removal process.

In any embodiments, any and/or all of the following features may be implemented in any combination and without limitation. The method may also include forming a gate region in the trench within the silicon channel layer such that the silicon channel layer is adjacent to a gate oxide of the gate region; removing the two silicon fins around the trench; and removing the sacrificial layer to expose a side of the silicon channel layer that is opposite the gate oxide. A pitch of the trench may be sufficient for a main gate region and a back gate region of a transistor. Widths of each of the two silicon fins may be between about 10 nm and about 25 nm; a width of the trench may be between about 30 nm and about 60 nm; a width of the sacrificial layer may be between about 0 nm and about 20 nm; and a width of the silicon channel layer ay be between about 3 nm and about 13 nm. Forming the sacrificial layer may include epitaxially growing the sacrificial layer on the sidewalls of the trench; and forming the silicon channel layer may include epitaxially growing the silicon channel layer on the sacrificial layer. The method may also include forming the sacrificial layer on a bottom of the trench, where the sacrificial layer may include silicon germanium, and a height of the sacrificial layer on the bottom of the trench is greater than a width of the sacrificial layer on the sidewalls of the trench. A germanium concentration in the sacrificial layer on the bottom of the trench may be different than a germanium concentration in the sacrificial layer on the sidewalls of the trench. The method may also include forming the gate oxide as a conformal layer on the silicon channel layer, and annealing the semiconductor structure at a temperature less than 1000 °C such that germanium in the sacrificial layer does not defuse into the silicon channel layer. The method may additionally include performing a chemical mechanical polishing (CMP) process to expose the silicon fin, where the CMP process may stop before exposing the silicon channel layer. The method may further include performing a Y-cut on the semiconductor structure before removing the silicon fin to expose the sacrificial layer. The method may also include filling a region left after removing the hard mask with polysilicon; and removing the silicon fin by etching the polysilicon and the silicon fin in a single process. Removing the silicon fin may be a self-aligned process to create a main gate region adjacent to a back gate region. The method may additionally include removing a layer of residual silicon from the sacrificial layer before removing the sacrificial layer. The method may further include, after removing the portion of the substrate beneath the sacrificial layers, removing a remaining portion of the substrate between the sacrificial layers. The method may also include performing a main gate recess and a main gate fill with silicon nitride between the sacrificial layers after removing the remaining portion of the substrate between the sacrificial layers. Removing the remaining portion of the substrate between the sacrificial layers may be a self-aligned process for exposing main gate regions. The sacrificial layers may include epitaxial silicon germanium. The sacrificial layers may include cup-shaped regions of material formed at bottoms of trenches for back gate regions, and the sacrificial layers are not connected to each other.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a top plan view of an exemplary processing chamber, according to some embodiments.

FIGS. 2A-2B illustrate top and perspective views of an 4 F² DRAM memory array, according to some embodiments.

FIGS. 3A-3B illustrate existing techniques for forming a silicon channel.

FIGS. 4A-4B illustrate flowcharts of methods of forming portions of a DRAM structure, according to some embodiments.

FIGS. 5A-5L illustrate incremental steps for forming a semiconductor structure for a DRAM array, according to some embodiments.

FIG. 6 illustrates a flowchart of a method for forming a portion of a DRAM structure to remove an underlying substrate from the backside of the structure, according to some embodiments.

FIGS. 7A-7D illustrate incremental steps for forming a portion of the semiconductor structure for a DRAM array to remove the substrate, according to some embodiments.

FIGS. 8A-8B illustrate flowcharts of methods of forming portions of a DRAM structure, according to some embodiments.

FIGS. 9A-9G illustrate incremental steps for forming a semiconductor structure for a DRAM array using a non-self-aligned technique, according to some embodiments.

### DETAILED DESCRIPTION

Historically, DRAM chip bit densities have been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, advanced memory structures, including vertical cell structures such as 4F² DRAM, and other devices having complex features come with their own challenges. For example, these devices typically use very thin, vertical silicon channels, where controlling the uniformity and thickness of the channel is key to proper device operation. Current methods use an overhead spacer mask to define the channel thickness, then rely on an etch process to create the channel. This leads to tapered channels from the etch that do not have a uniform thickness throughout the vertical height. The channel surfaces may also be relatively rough resulting from a combination of the first trench and second trench etch profiles and the very narrow critical dimensions (CD) of these trenches. Additionally, after the capacitors are formed and the DRAM structure is flipped over for backside processing, removing the silicon substrate requires specific stop layers that add additional processing steps to form.

The present technology overcomes these and other problems by epitaxially growing a silicon channel laterally out from the straight vertical sidewalls of the initial trench. Instead of etching a very narrow trench, the trench in silicon is etched using a hardmask stack, leaving a hard mask, such as silicon nitride, and the trench width can be increased to reduce tapering and roughness. A sacrificial layer (e.g., silicon germanium) may then be epitaxially grown on the trench sidewalls, followed by a layer of epitaxial silicon for the channel. The back gate oxide and metal may then be formed within the remain width of the trench. Later in the manufacturing process, the space between the initial hard mask features used to define the silicon fins are filled with a different material, such as oxide, and then planarized to the initial hard mask height, and then the initial hardmask may be removed (and optionally replaced with polysilicon) to allow the silicon fins to be exposed (and optionally along with some of the sacrificial layer) for a second Si trench etch which is now self-aligned to the channel. These fins can then be removed to expose some or all of the sacrificial layer. The sacrificial layer may then be removed selectively to expose the silicon channel opposite of the back gate oxide. Additionally, a relatively thick portion of the sacrificial layer may be formed at the bottom of the trenches. This bottom portion of the sacrificial layer may remain throughout the front side processing to be later used as a stop layer when removing the bulk of the underlying substrate during backside processing.

Although the remaining disclosure will routinely identify specific deposition and etch processes utilized for forming vertical cell access array transistors (VCATs), such as a 4F² DRAM device, it will be readily understood that the systems and methods are equally applicable to other memory devices, including 6F² DRAM arrays, 3D NAND, and/or 3D DRAM device, junction-less SONOS memory, floating body cell memory, oxide semiconductor memory, ferroelectric memory, and other devices having high aspect ratio features, and orientations thereof, as well as processes for forming such devices. Accordingly, the technology should not be considered to be so limited as for use with these specific devices or systems alone. The disclosure will discuss one possible semiconductor device that may include one or more components, utilizing one or more power lines and/or signal lines according to embodiments of the present technology before additional variations and adjustments to this apparatus according to embodiments of the present technology are described.

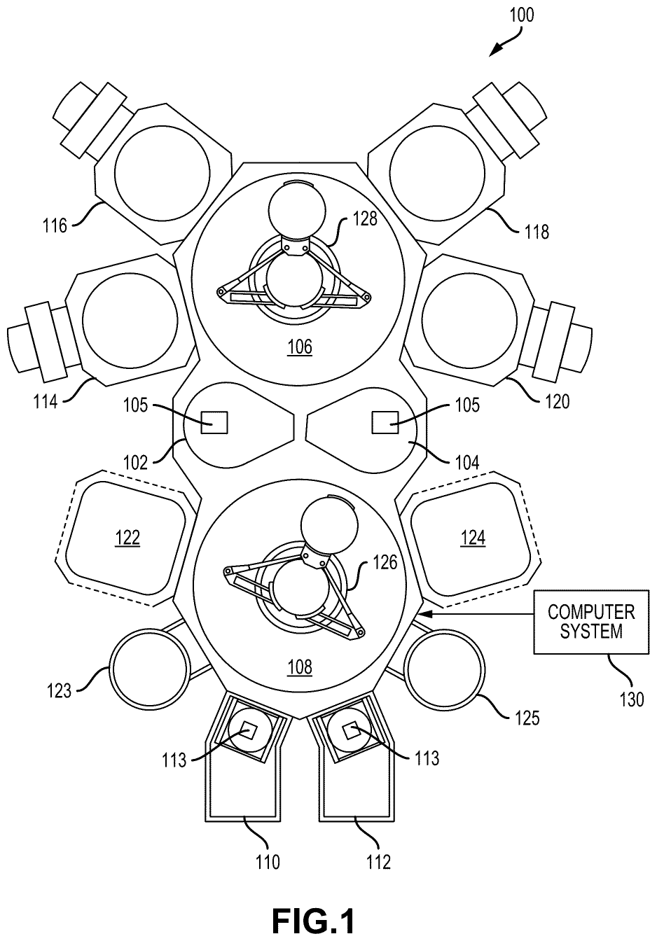

FIG. 1 illustrates a top plan view of a multi-chamber processing system 100, which may be specifically configured to implement aspects or operations according to some embodiments. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108 and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

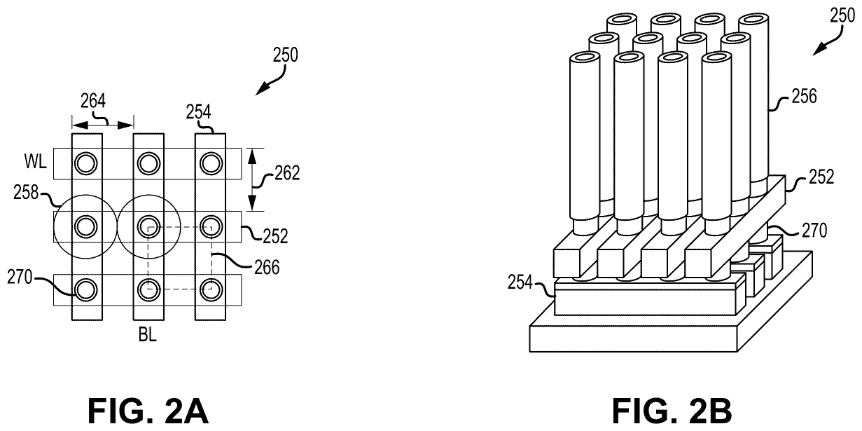

FIGS. 2A-2B illustrate top and perspective views of an 4 F² memory array 250, according to some embodiments. The memory array 250 may include a plurality of word lines 252 that are arranged in a first layer over a substrate. The word lines 252 may intersect with a channel of a respective transistor and be conductive traces that are used to select a word line of memory cells in the memory array 250. The memory array 250 may also include a plurality of bit lines 254 that electrically connect to a source/drain region of a respective transistor and be arranged in a second layer over a substrate. The plurality of bit lines may be conductive traces that are used to select a bit line of memory cells in the memory array 250. Activating one of the plurality of bit lines 254 and one of the plurality of word lines 252 may select an individual cell in the memory array 250. The first layer and the second layer may include different metal layers formed at different times during manufacturing process. For example, the first layer with the word lines 252 may be formed above the second layer with the bit lines 254 such that the two layers do not intersect.

A plurality of vertical memory cells may be arranged over intersections between the plurality of word lines 252 and the plurality of bit lines 254. Each of the plurality of vertical memory cells may include a vertical transistor, which may be referred to as a vertical pillar transistor or vertical column transistor. A channel material for the transistor may be formed from a single-crystalline silicon, poly-crystalline silicon, amorphous silicon, silicon carbide, silicon germanium, germanium, an oxide semiconductor, including indium gallium zinc oxide, 2D materials including molybdenum disulfide, gallium nitride, carbon nanotubes, graphene, boron arsenide, combinations thereof, or any other substrates discussed in greater detail herein. Furthermore, dopants may be introduced based upon the device need, for any one or more of the materials discussed herein. This silicon channel may be formed by etching the substrate, as shown in the illustrated embodiments, or may be deposited onto the substrate, depending upon the desired device. Each of the plurality of vertical memory cells may also include a vertical capacitor 256. The vertical memory cell may operate by storing a charge on the vertical capacitors 256 to indicate a saved memory state. However, while FIGS. 2A-2B illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 2A-2B. Thus, it should be understood that any suitable orientation may be utilized with the present technology.

It is useful to characterize the dimensions of the unit cell area 266 for this conventional 4F² memory array for comparison to the simple memory array described below. For example, a capacitor footprint 258 may be defined as a circular area around each vertical capacitor 256. The capacitor footprint 258 may include the horizontal cross-sectional area of the capacitor expanded out until the cross-sectional area contacts a capacitor area from a neighboring memory cell. Assuming that the word line pitch 262 for the plurality of word lines 252 and the bit line pitch 264 for the plurality of bit lines 254 may be defined as 2F. This leads to an overall cross-sectional area of 4F² for a unit cell area 266.

A technical problem arises in existing techniques for fabricating 4F² DRAM arrays. Specifically, these vertical memory cells utilize very thin, narrow, vertical silicon channels. Accurately and uniformly controlling the width of the silicon channels is key to ensuring proper device performance. Current methods use a spacer mask over silicon in order to define the width of the silicon channel during the channel etch. When the channel etch is performed, the silicon remaining under the spacer mask may form the silicon channel.

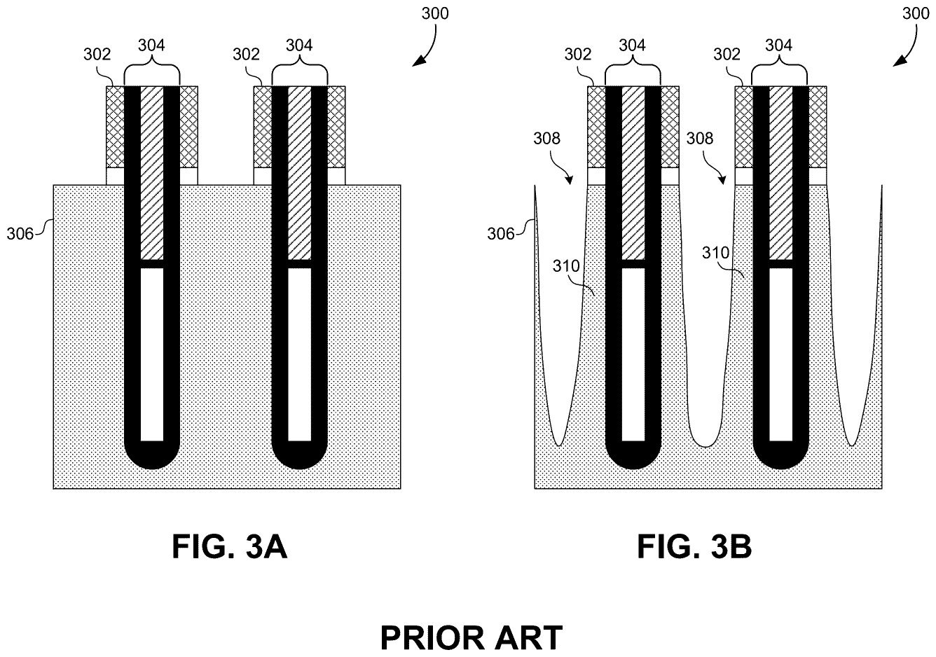

FIGS. 3A-3B illustrate existing techniques for forming a silicon channel. FIG. 3A illustrates a semiconductor structure 300 for a partially formed 4F² DRAM array. At this stage, the gate regions 304 have been formed in the silicon 306 (e.g., including the back-gate metal, the gate metal, the gate oxide, and so forth). In order to define the width of the silicon channels, a spacer mask 302 has been formed adjacent to a top portion of the gate region 304. FIG. 3B illustrates the result of an etch process used to form the silicon channels 310. As illustrated, the silicon channels 310 are formed as the vertical regions along sidewalls of the gate regions 304. A directional etch may be used to remove the silicon 306 that is not shielded by the spacer mask 302, and thereby leave behind the silicon channels 310 adjacent to the gate regions 304.

This technique has the advantages of making the channel self-aligned to the trenches for the back-gates of the DRAM devices. This technique also ensures that the dimensions and spacing of the silicon channels 310 can be controlled and uniform at the top of the channels 310 when forming the spacer mask 302. However, this technique also relies on an etch process to form the silicon channels 310 rather than a deposition process. When etching such a deep and narrow region (i.e., a region with such a large critical dimension(CD)), the etch may not create a silicon channel 310 that is uniform throughout its height. Instead, the trenches 308 defining the silicon channels 310 may taper, resulting in a narrower CD at the top of the trenches 308 and a much larger CD at the bottom of the trenches 308. This tapering effect results in silicon channels 310 that are thicker at the bottom of the device than at the top of the device. Additionally, the sidewall surfaces of the silicon channel 310 are defined by two etch processes, namely (1) the earlier-performed back-gate etch, and (2) the channel etch depicted in FIG. 3B. This may result in sidewalls that are relatively rough and nonuniform.

The embodiments described herein present a technique for forming a uniform, self-aligned channel by depositing a sidewall epi with a uniform thickness. A sacrificial silicon germanium layer may also be applied to ensure that the sidewall surface of the channel is smooth and to align the channel etch with the earlier-performed back-gate trench.

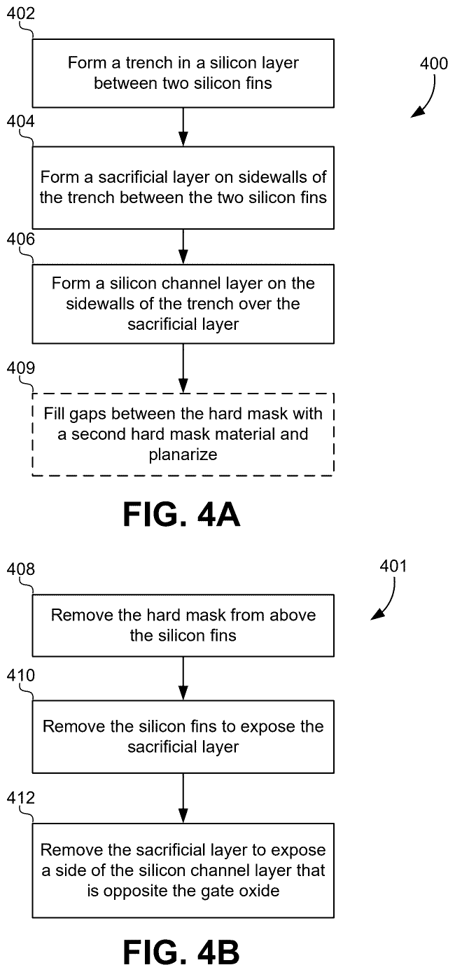

FIGS. 4A-4B illustrate flowcharts of methods 400, 401 of forming portions of a DRAM structure, according to some embodiments. The methods may be performed in a variety of processing chambers, including processing chamber 100 described above in FIG. 1. The methods 400, 401 may include a number of optional operations, which may or may not be specifically associated with various embodiments. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized, as well as other orientations for non-vertical cell transistors. The methods 400, 401 may be specifically used in forming a 4F² DRAM structure. However, the methods 400, 401 may also be used in other memory structures as well.

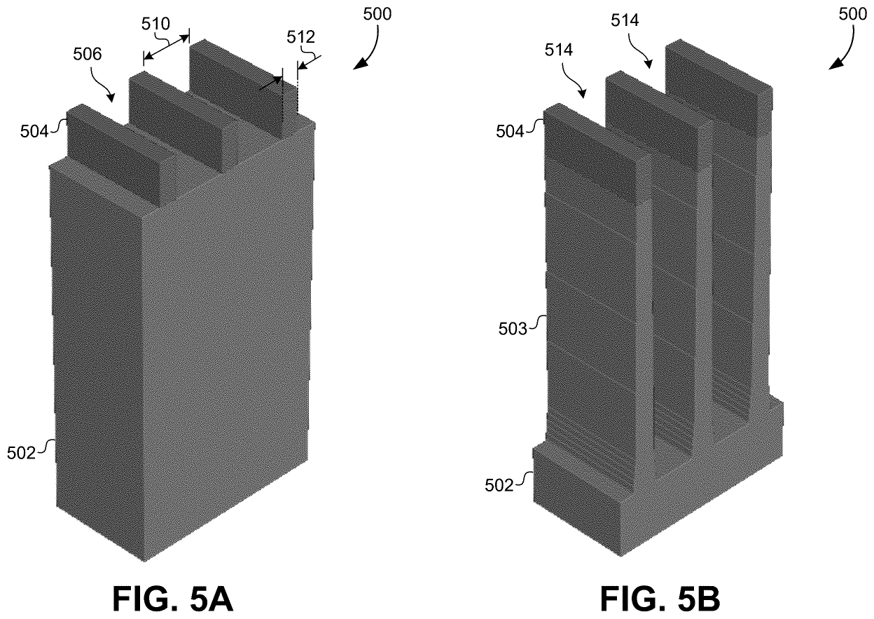

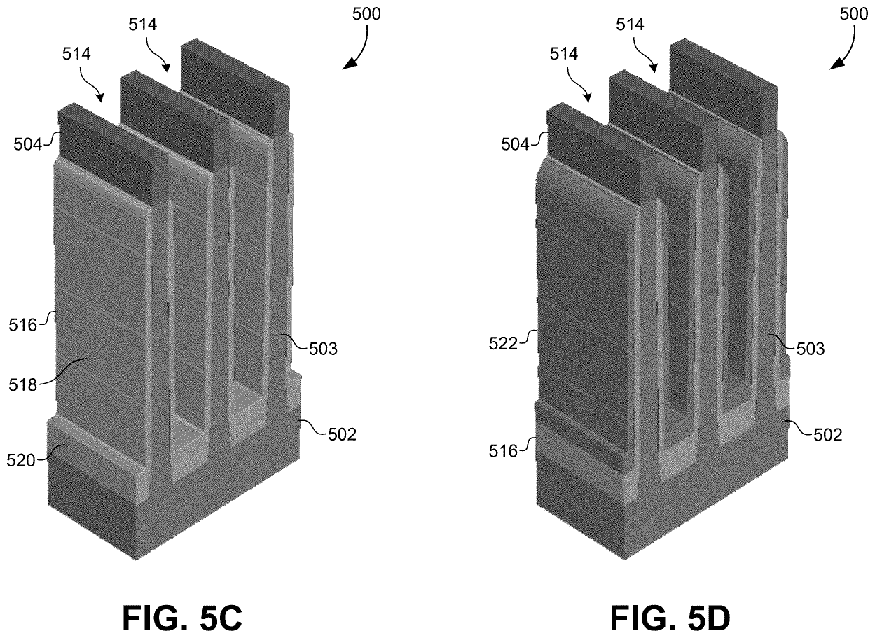

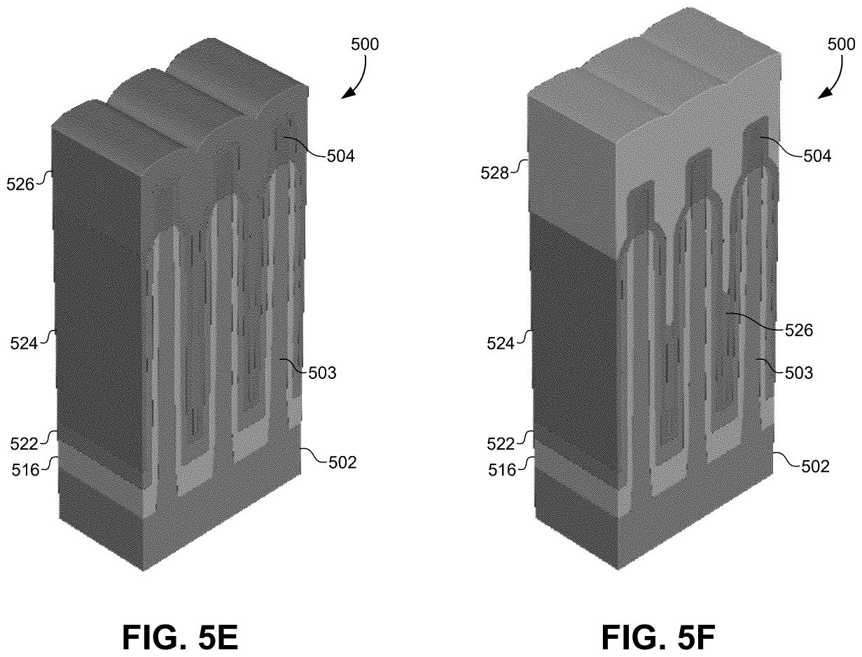

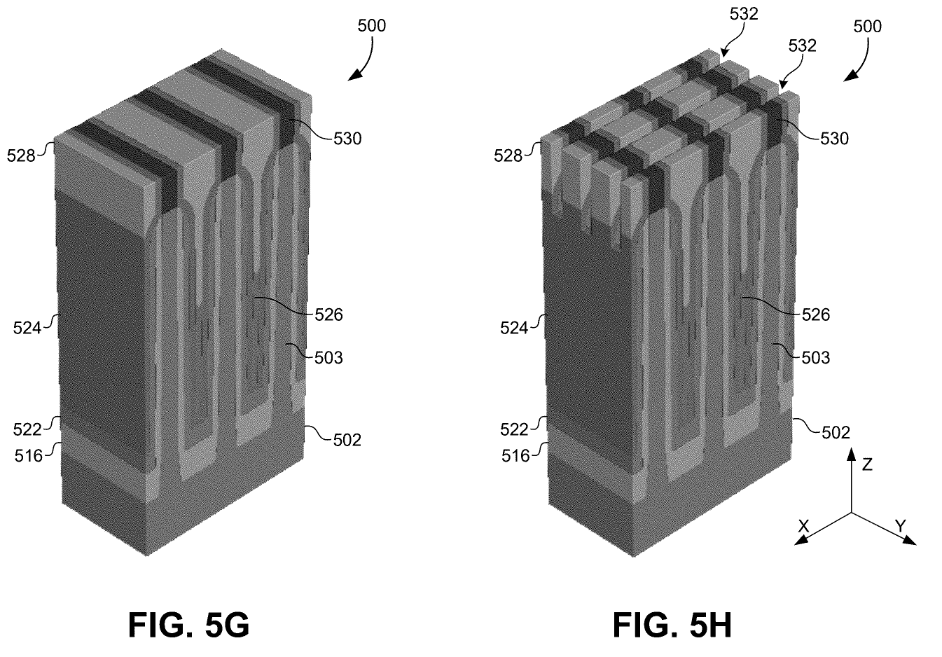

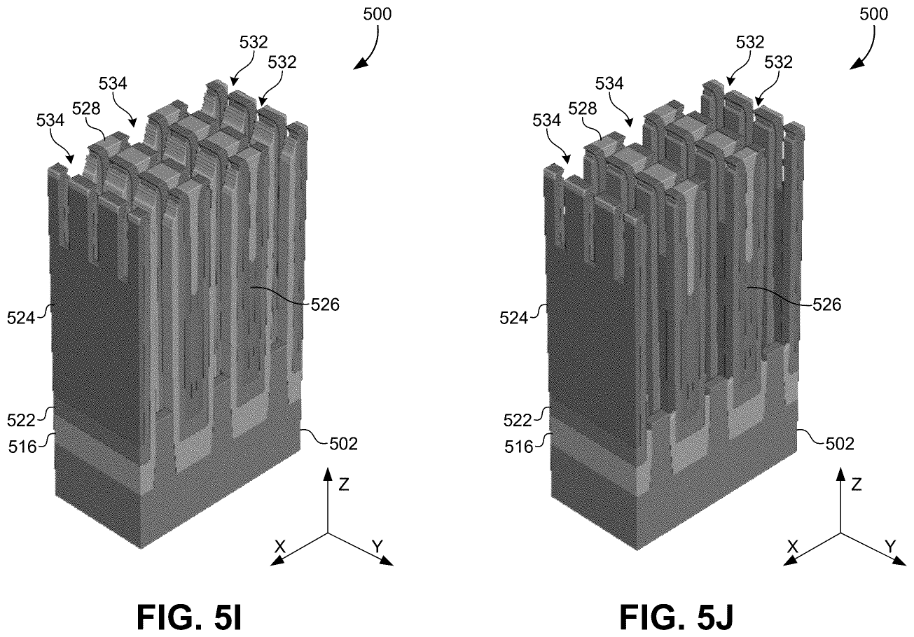

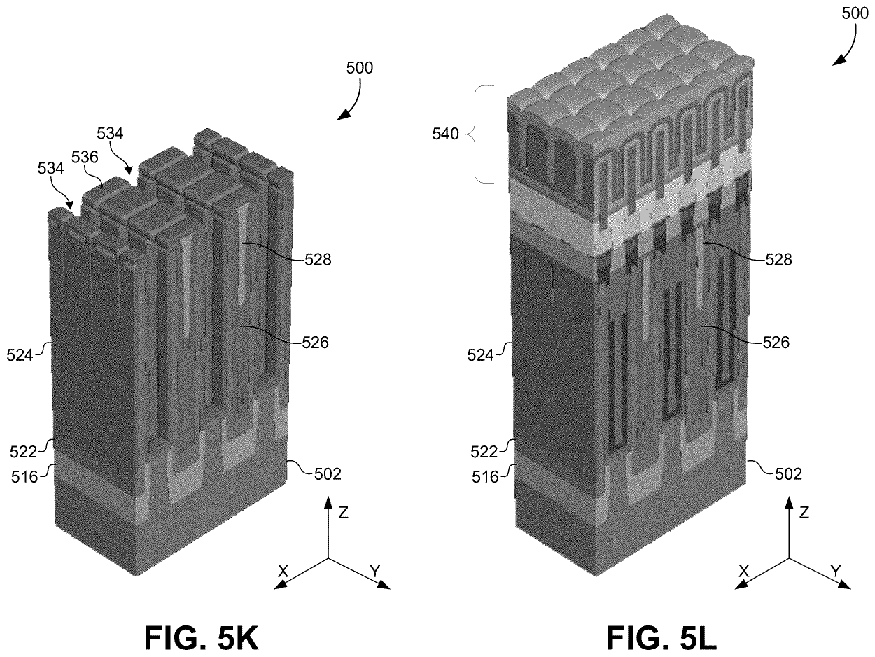

FIGS. 5A-5L illustrate incremental steps for forming a semiconductor structure 500 for a DRAM array, according to some embodiments. The incremental structures illustrated in these figures may represent example structures that may be performed by the operations of method 400. However, the structures are provided only by way of example and are not meant to be limiting. The operations of methods 400, 401 may be broader than these example structures, and additional processes and structures may be included in different embodiments.

Beginning with method 400, a silicon channel layer may be formed by first etching a relatively wide trench in the silicon substrate. The sidewalls and/or bottom of this trench may then be conformally coated with a sacrificial layer, such as silicon germanium. In some embodiments, the sacrificial layer may be epitaxially grown on the sidewalls and bottom of the trench. Finally, the silicon channel layer may also be epitaxially grown on the sidewalls and bottom of the trench over the sacrificial layer.

The method 400 may include forming a trench in a silicon layer between two silicon fins (402). FIG. 5A illustrates an initial semiconductor structure for forming a memory array. The techniques described below are compatible with any type of substrate. For example, instead of using a traditional silicon-on-insulator (SOI) structure, such as a silicon-on-oxide structure, for forming the memory array, some embodiments may use a silicon substrate 502 as the underlying substrate. The bare silicon may be referred to herein as a silicon-containing layer. The silicon-containing layer may include a silicon substrate made substantially of silicon (e.g., greater than 98% silicon). In this case, the silicon-containing layer may also be referred to as simply a silicon layer or a silicon substrate. Alternatively, the silicon-containing layer may include a layer of silicon material formed over a substrate of any type.

In order to pattern the silicon substrate 502, a hard mask 504 may be formed over a top layer of the silicon substrate 502. Although not shown explicitly, the hard mask 504 may be formed as a uniform layer across the top of the silicon substrate 502 and may include a pad oxide (not shown). The hard mask 504 may then be patterned and opened in order to expose a portion of the silicon substrate 502 to be etched. In contrast to existing techniques that etch a much narrower trench for the back gate, some embodiments may etch a significantly wider trench. For example, existing processes would etch a trench at this stage that is between about 10 nm and about 15 nm wide (e.g., 13 nm wide). In contrast, the with 510 of the openings 506 of the hard mask 504 may be between about 30 nm and about 60 nm wide (e.g., about 40 nm wide). The with 510 of the trench may also be characterized by the devices that will fit within the trench pitch. For example, the trench pitch may be sufficient to accommodate both a back gate region and a main gate region that are horizontally adjacent to each other. Alternatively, the width 510 of these embodiments may be characterized in comparison to the width of the trench using existing techniques, where the width 510 is 2×, 3×, or 4× the width of trenches etched in the existing techniques. Since the depth of the etch is the same, widening the trench results in an aspect ratio for the etch that is one half, one third, one fourth, etc., of the aspect ratio required by existing techniques. The width 512 of the remaining portions of the hard mask 504 may be between about 10 nm and about 25 nm wide (e.g., about 20 nm wide). The width 510 may also be defined by the desired pitch of the DRAM cells. For example, if the final DRAM cell pitch is to be 30 nm, then the pitch of the openings 506 in the hard mask 504 may be double (e.g., 60 nm).

FIG. 5B illustrates trenches 514 etched in the openings of the hard mask 504. As described above, existing techniques used much narrower trenches relative to the trench depth, resulting in a relatively large CD for the trenches. This large CD created a tapering effect at the bottom of the trench and relatively rough sidewalls. In contrast, the etch illustrated in FIG. 5B creates much wider trenches 514. This reduces the tapering and results in a much more uniform and straighter sidewall in the silicon substrate 502. For example, the final taper of the sidewalls of the trenches 514 may be approximately 89.5°. The trenches 514 may be defined by silicon fins 503 that remain under the hard mask 504. In the three-dimensional DRAM array, these silicon fins 503 may be long ridges of silicon that extend along the silicon substrate 502.

The method 400 may also include forming a sacrificial layer on sidewalls of the trench between the two silicon fins (404). FIG. 5C illustrates the formation of a sacrificial layer 516 on the exposed silicon in the trenches 514. The sacrificial layer 516 may be selectively formed only on the exposed silicon of the silicon fins 503 and the silicon substrate 502 in the trenches 514. For example, the sacrificial layer 516 may be grown epitaxially on the exposed silicon fins 503 and the silicon substrate 502. In some embodiments, the sacrificial layer 516 may be formed as epitaxial silicon germanium. The exposed silicon trench sidewalls of the silicon substrate 502 may have a 110 plane, and the exposed silicon on the bottom of the trenches 514 may have a 100 plane. The differences in these lattice orientations may cause a bottom portion 520 of the sacrificial layer 516 to grow at a faster rate than a sidewall portion 518 of the sacrificial layer 516. Therefore, this layer at the bottom of the trenches 514 may have a greater thickness than a width of the sacrificial layer 516 on the sidewalls of the trenches 514. The bottom portion 520 may also have a different germanium concentration than a germanium concentration in the sidewall portion 518, which may aid in removing the sidewall portion 518 while leaving the bottom portion 520 as described further below. The thickness of the bottom portion 520 of the sacrificial layer 516 may be grown to compensate for any taper that may result from downstream etch processes that are described in detail below. For example, the thickness of the sidewall portion 518 of the sacrificial layer 516 may be between about 3 nm and about 5 nm thick. The thickness of the bottom portion 520 of the sacrificial layer 516 may be between about 10 nm and about 20 nm thick. In some embodiments, this thickness may be reduced to 0 nm for both the bottom portion 520 and/or the sidewall portion 518 of the sacrificial layer 516. For example, the sacrificial layer 516 may be omitted in some embodiments.

The method 400 may further include forming a silicon channel layer on the sidewalls of the trench over the sacrificial layer (406). FIG. 5D illustrates the formation of a channel layer 522. In some embodiments, the channel layer 522 may also be grown epitaxially on the sacrificial layer 516. For example, the channel layer 522 may be a silicon channel layer that is grown epitaxially to a predetermined thickness of between about 9 nm and about 13 nm on the sidewall of the underlying sacrificial layer 516. This process generates a very high quality silicon channel layer with a thickness that may be very accurately controlled. Additionally, the thickness of the channel layer 522 may be uniform throughout the height of the channel layer 522 due to the epitaxial growth.

At this stage, the width and geometry of the channel regions have been defined by the epitaxial growth of the channel layer 522. Additional processes are now described that form the back gate region inside of the channel layer 522 and prepare the semiconductor structure 500 to remove the silicon fins 503 and expose the channel layer 522. These processes may be viewed as a separate stage of the overall manufacturing process. Therefore, some embodiments may also include forming a gate region in the trench within the silicon channel layer such that the silicon channel layer is adjacent to a gate oxide of the gate region.

FIG. 5E illustrates how the back gate regions of the semiconductor structure 500 may first be filled with a gate oxide (GOX) 524 and a back gate metal 526. In some embodiments, a silicon oxide liner may first be formed in the trenches 514 over the channel layer 522 to form the gate oxide 524. For example, an atomic layer deposition (ALD) process may be used to grow a layer of silicon oxide along the sidewalls and bottom of the trenches 514. The gate oxide 524 may also be formed on top of the remaining hard mask 504. The thickness of the gate oxide 524 may vary in different embodiments. For example, the thickness of the gate oxide 524 may range from between about 1 nm to about 6 nm. Alternatively, the gate oxide 524 may be replaced with an air gap. For example, a dummy fill may be used at this stage which may be replaced in downstream processes. The dummy fill may later be fully removed downstream without a backfill in order to form an air gap.

In some embodiments, a low temperature anneal may also be performed. Embodiments using silicon germanium for the sacrificial layer 516 may not be compatible with higher temperature anneal processes, since higher temperatures may cause the silicon germanium to diffuse. Therefore, this anneal process may be performed at temperatures less than or about 600 °C, less than or about 700 °C, less than or about 800 °C, less than or about 900 °C, or less than or about 1000 °C, depending on the process time at temperature and other parameters, and the materials used. After the gate oxide 524 is annealed, remaining volume of the trenches 514 may then be filled with a back gate metal 526. The back gate metal 526 may substantially fill the trenches 514 without any significant seams or voids. The back gate metal 526 may also result in an overburdened of the back gate metal 526 being formed on top of the semiconductor structure 500 as illustrated in FIG. 5E. Any suitable material may be used for the back gate metal 526, such as titanium nitride, tungsten, molybdenum, and other similar materials.

FIG. 5F illustrates how the back gate metal 526 can be recessed and covered with a dielectric plug (e.g., SiO). In some embodiments, a CMP or etch process may be applied to the semiconductor structure 500 in FIG. 5E to remove the overburden of the gate metal 526. The back gate metal 526 may thus be recessed from the back gate trenches 427 until only a portion of the back gate metal 526 remains at the bottom of the trenches 514. As illustrated in FIG. 5F, the height of the back gate metal 526 may extend from the bottom of the trench up to a predetermined level. The timing of this etch process may be controlled to remove a precise amount of the back gate metal 526 until a predetermined height is reached.

The method 400 may also optionally include filling gaps between the hard mask 504 with a second hard mask material and planarizing the semiconductor structure 500 to expose the hard mask 504 (407). After recessing the back gate metal 526, a dielectric 528 may be formed on the semiconductor structure 500. This dielectric 528 may fill the top portion of the trenches above the back gate metal 526. This dielectric 528 may act as a second hard mask material. An overburdened of the dielectric 528 may be formed on top of the semiconductor structure 500 as illustrated in FIG. 5F. The dielectric 528 may include silicon oxide or any other similar material. Although not shown explicitly in FIG. 5F, the semiconductor structure 500 may be planarized using a CMP or etch process to create a flat surface and expose the hard mask 504.

After forming the back gate region, a processing stage may be executed to expose the silicon channel layer that is opposite of the back gate oxide by removing the silicon fins 503 and a portion of the sacrificial layer 516. Turning back to FIG. 4B, the method 401 may be used to form a portion of the DRAM structure by exposing the silicon channel layer. Since this subprocess may be considered separately from other subprocesses when manufacturing a DRAM structure, the method 401 may begin by receiving a semiconductor structure that includes a silicon fin underneath a hard mask; a sacrificial layer on a sidewall of a silicon fin; a silicon channel layer on the sacrificial layer; and a gate oxide on the silicon channel layer.

The method 401 may include removing the hard mask from above the silicon fin (408). FIG. 5G illustrates replacing the hard mask 504 with a self-aligned fill material 530. The overburden of the dielectric 528 and the top portion of the gate oxide 524 may be removed from the top of the semiconductor structure 500 using a removal process, such as a CMP process or an etch process. The material of the hard mask 504 may be used as a stop layer for this removal process. For example, for a hard mask 504 that includes nitride, the nitride material may be used as a CMP stop layer to halt the removal process when the top of the hard mask 504 is exposed.

After exposing the top of the hard mask 504, the material of the hard mask 504 may be exhumed from the top of the semiconductor structure 500. For example, an etch process may be used that is selective to the hard mask material, such as an etch that is selective to nitrides. Both wet and/or dry etch processes may be compatible with this step. The resulting trench that is left after removing the hard mask 504 may be completely self-aligned with the underlying silicon fins 503. The trench may be formed in the X direction for reference. As illustrated in FIG. 5A, the hard mask 504 is used to form the silicon fins 503 in the silicon substrate 502, and thus removing the hard mask 504 generates a trench that is self-aligned with the silicon fins 503. These trenches may then be filled with a fill material 530. For example, some embodiments may use polysilicon, silicon germanium, or any other material with etch properties that allow the fill material 530 to be etched with silicon.

FIG. 5H illustrates a Y cut that may be performed on the semiconductor structure 500. For example, the Y cut may use a patterned etch process to remove material and form trenches 532 in the Y direction. The fill material 530, the dielectric 528, the gate oxide 524, the silicon fins 503, the channel layer 522, and the sacrificial layer 516 to a predetermined depth. For example, the Y cut may form trenches 532 that extend at least down to expose the channel layer 522, the sacrificial layer 516, and/or the silicon fins 503. As a variation, this Y cut may also be performed in upstream processes and then back filled with a fill material. Therefore, performing the Y cut at this stage is not required, and this operation may alternatively be performed in previous stages.

The method 401 may additionally include removing the silicon fin to expose the sacrificial layer (410). At this stage, the mask is now separate in both the X and Y directions. In the X direction, the fill material 530 (e.g., polysilicon) may be different from the underlying silicon in the Y direction. However, the fill material 530 and the silicon of the silicon substrate 502 may easily be etched together.

FIG. 5I illustrates the removal of the silicon fins 503 from between the back gate regions. The etch may be configured to remove the optional fill material 530 (e.g., polysilicon) and at least a portion of the silicon fins 503 of the silicon substrate 502. For example, the etch may be selective to silicon and the fill material 530, while not being selective to the silicon germanium of the sacrificial layer 516. The etch may be timed such that the silicon fins 503 of the silicon substrate 502 may be removed down to a predetermined depth. For example, the silicon fins 503 may be removed to a level that is just above the bottom of the back gate metal 526 as illustrated in FIG. 5I. Although not clearly visible in FIG. 5I, any exposed silicon in the Y direction may also be removed since this silicon would not be protected by any overlying layers. It should be emphasized that this removal of the silicon fins 503 is a self-aligned process since the fill material 530 that replaced the mask layer 504 already defined the width of the silicon fins. Therefore, no new masks are needed to be aligned with the existing semiconductor structure 500 in order to ensure that these fins are removed with precise dimension control of the final channel. After the X and Y cuts are made in the semiconductor structure 500, the individual devices will be cut into separate pillars as illustrated in FIG. 5I.

Depending on the controllability and precision of the etch process, some residual silicon from the silicon fins of the silicon substrate 502 may remain on the sidewalls of the sacrificial layer 516. The majority of the silicon may be removed by the etch, and any remaining silicon on the sacrificial layer 516 will typically be oxidized. Therefore, some embodiments may perform an optional process of using a selective etch (selectivity to the sacrificial liner, such as silicon germanium) that removes any remaining oxidized silicon and silicon pillar on the sidewalls of the Y trenches 534. This selective etch may not affect the silicon at the bottom of the Y trenches 534 or the sacrificial layer 516 (e.g., silicon germanium). This may fully expose the sacrificial layer 516 on the sidewalls of the Y trenches 534.

The method 401 may further include removing the sacrificial layer to expose a side of the silicon channel layer that is opposite the gate oxide (412). FIG. 5J illustrates the removal of the sacrificial layer 516 from the sidewalls of the Y trenches 534. An etch process maybe use that is selective to the specific material used for the sacrificial layer 516. For example, when silicon germanium is used, a dry plasma-based etch (e.g., HBr) or an atomic layer etch (Cl₂-based) may be used to selectively remove silicon germanium without damaging the silicon or other materials in the semiconductor structure 500. Removing the sacrificial layer 516 from the sidewalls exposes the silicon of the channels 522. In some embodiments, this etch process may be a timed etch rather than an exhume etch. The timing of the etch may be controlled to remove the sacrificial layer 516 from the sidewalls of the Y trenches 534 without significantly recessing the sacrificial layer 516 from the bottom of the Y trenches 534. As illustrated in FIG. 5J, the sacrificial layer 516 at the bottom of the Y trenches 534 may form cup-shaped regions that are useful for providing a self-aligned feature for backside processing as described below. Note that some recessing may be tolerated in order to remove all of the sacrificial layer 516 from the sidewalls of the trenches 534.

In comparison to existing techniques, these processes greatly improve the geometry, uniformity, smoothness, and quality of the silicon channel layer 522. Instead of defining the width of the channel layer 522 using a spacer mask and a vertical etch, the width of the channel layer 522 is defined by the very controlled epitaxial growth of the silicon as shown in FIG. 5D.

FIG. 5K illustrates the formation of a gate oxide 536 for the gate regions of the individual DRAM cells. The gate oxide 536 may be formed from any oxide material (e.g., silicon oxide). The gate oxide 536 may be formed using an ALD process or a CVD process to conformally coat the exposed surfaces of the semiconductor structure 500 with the gate oxide 536. In contrast to the previous formation of the back gate oxide, the formation of the gate oxide 536 may utilize a high-temperature anneal. The only remaining silicon germanium of the sacrificial layer 516 in the semiconductor structure 500 is in the silicon substrate 502 below the gate structures. Therefore, any diffusion of the germanium during the high temperature anneal will not affect the channel layer 522 of the DRAM cells. For example, a high-temperature anneal of greater than 600 °C, greater than 700 °C, greater than 800 °C, greater than 900 °C, greater than 1000 °C, and/or greater than 1200 °C may be used, depending on the embodiment.

FIG. 5L illustrates the formation of capacitive structures 540 on top of the semiconductor structure 500. In current 4F² DRAM processes, the front side of the devices may be finished by adding the capacitive structures 540 that include capacitors and other electrical connections. The formation of the remaining portions of the transistors, the word lines, and/or capacitors may be carried out using standard techniques that are well known in the art and beyond the scope of this disclosure to arrive at the structure illustrated in FIG. 5L.

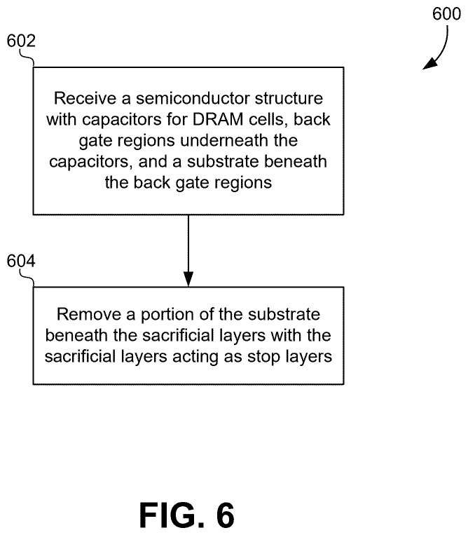

After forming the capacitive structures 540, a processing stage may be executed to flip the substrate to the backside and performed backside processing operations to form bit lines, form main gate connections, and so forth. FIG. 6 illustrates a flowchart 600 of a method for forming a portion of a DRAM structure to remove an underlying substrate from the backside of the structure, according to some embodiments. Since this subprocess may be considered separately from other subprocesses when manufacturing a DRAM structure, the method 600 may begin by receiving a semiconductor structure that includes capacitors for DRAM cells on a top side of the silicon structure; back gate regions for the DRAM cells underneath the capacitors in the silicon structure where the back gate regions include sacrificial layers beneath the back gate regions; and a substrate on a bottom of the silicon structure and beneath the back gate regions (602). The method 600 may be performed in a variety of processing chambers, including processing chamber 100 described above in FIG. 1. Method 600 may include a number of optional operations, which may or may not be specifically associated with various embodiments.

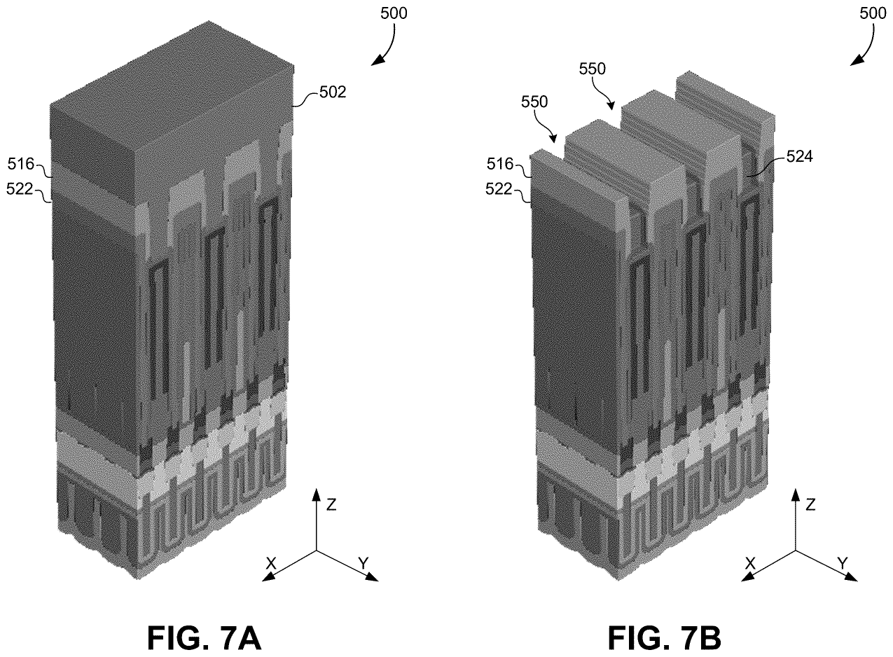

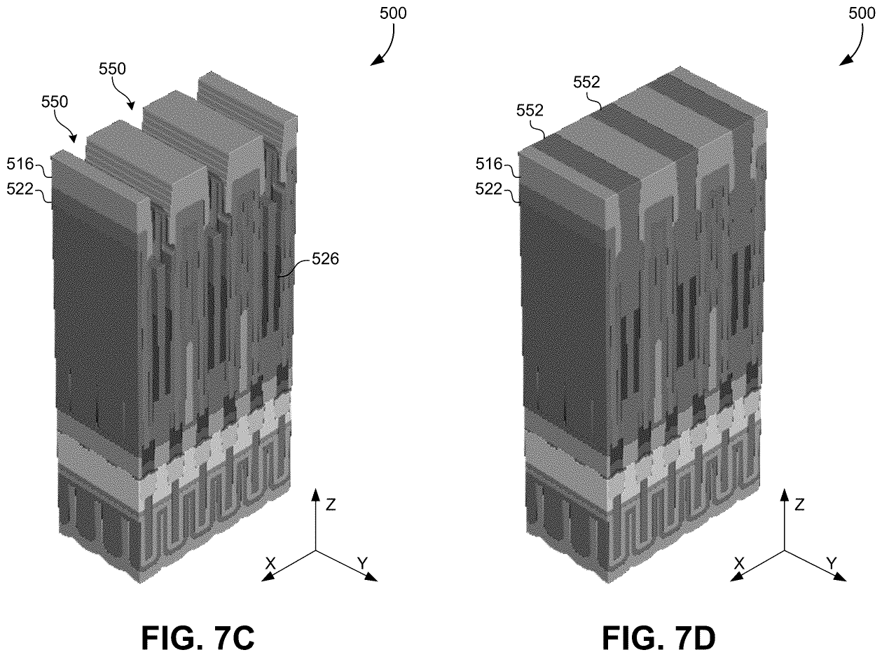

FIGS. 7A-7D illustrate incremental steps for forming a portion of the semiconductor structure 500 for a DRAM array to remove the substrate 502, according to some embodiments. The incremental structures illustrated in these figures may represent example structures that may be performed by the operations of method 600. However, the structures are provided only by way of example and are not meant to be limiting. The operations of method 600 may be broader than these example structures, and additional processes and structures may be included in different embodiments.

FIG. 7A illustrates the semiconductor structure 500 flipped over to expose the backside of the semiconductor structure 500 for backside processing. This allows the process to form backside structures, such as a backside bit line and other components. Some embodiments may also form electrical connections with the main gate and other transistor components. The semiconductor structure 500 may include the silicon substrate 502 and regions of the sacrificial layer 516. As described above, the sacrificial layer 516 may have properties that allow the sacrificial layer 516 to be etched simultaneously with silicon, or to be etched separately from silicon depending on the characteristics of the etch process. For example, the silicon substrate 502 may include plain silicon, while the sacrificial layer 516 may include silicon germanium or similar materials.

The method 600 may also include removing a portion of the substrate beneath the sacrificial layers, where the sacrificial layers may act as stop layers for a removal process (604). FIG. 7B illustrates the removal of the silicon substrate 520. In order to expose the electrical contacts on the backside of the semiconductor structure 500, the silicon substrate 502 may be removed. In existing techniques, removing the silicon substrate 502 was very difficult without also damaging or unintentionally exposing some of the underlying layers without adding an additional stop layer. However, since these embodiments add the sacrificial layer 516 early in the process, this sacrificial layer 516 may act as a very effective stop layer when removing the semiconductor substrate 502. For example, a CMP process may be used to remove a bulk of the silicon substrate 502. The sacrificial layer 516 (e.g., silicon germanium) may act as a CMP stop layer to halt the CMP process when the sacrificial layer 516 is exposed. Alternatively, an etch process may be used to remove the silicon substrate 502 with the sacrificial layer 516 acting as an etch stop layer for the etch process. Recall that the sacrificial layer 516 that remained on the bottom of the semiconductor structure 500 (now on the top, after flipping the semiconductor structure 500) was epitaxially grown thicker than the sacrificial layer 516 on the sidewalls of the trench. This thicker region of the sacrificial region 516 may provide a strong structure for acting as a stop layer.

Additionally, the gate oxide 524 formed earlier in the process may act as an additional stop layer for removing any residual silicon from the silicon substrate 502 between the areas with the sacrificial layer 516. An additional etch process may be used that is selective to the silicon 502 and not selected to the sacrificial layer 516 or the material of the gate oxide 524. This completely removes any of the exposed silicon of the silicon substrate 502. At the same time, this has no effect on the channel silicon, which is still protected by the gate oxide 524 and/or the sacrificial layer 516. The resulting semiconductor structure 500 may include trenches 550 between the adjacent regions of the sacrificial layer 516. Since the sacrificial layer 516 and the gate oxide 524 can act as stop layers, no additional stop layers are needed for this removal. This saves significant time and/or resources by reducing the number of processing steps required for the DRAM array.

FIG. 7C illustrates the gate oxide breakthrough and main gate recess on the semiconductor structure 500. First, the gate oxide 524 may be removed to expose the transistor gate region. This allows backside access to the transistor and exposes the gate region for further processing. This also enables backside word line formation and integration with the transistors. In some embodiments, a wet etch (e.g., HF HF-based chemistries) can be used to selectively remove silicon dioxide without damaging any of the underlying layers. Alternatively, atomic layer etching or dry plasma etching (e.g., CF₄, CHF₃, or SF₆-based plasmas) may be used to selectively etch the gate oxide.

Additionally, the gate metal 526 for the main gate may be recessed to isolate the gate from the underlying bit lines that will be formed later in the process. The gate metal 529 may be removed using various techniques, such as wet etching (e.g., H₂O₂-based or NH₄OH-based chemistries to selectively remove metals like TiN), ALE, and/or dry plasma etching (e.g., Cl₂, BCl₃, or SF₆-based plasmas may be used to anisotropically etch the gate metal 526).

FIG. 7D illustrates how the trenches 550 formed by removing the silicon substrate 502, gate oxide 524 and gate metal 526 may be filled with a fill material 552. For example, silicon nitride may be used as a fill material 552 to fill these trenches 550 using any suitable deposition process. Any overburdened may be polished or removed to create a flat surface on the top of the semiconductor structure 500. This allows the remaining sacrificial layer 516 to be removed to expose the main gate regions of the transistors. Note that the sacrificial layer 516 creates trenches 515 that are self-aligned with the underlying gate metal to be recessed. Additionally, after the trenches are filled with the fill material 552, removal of the sacrificial layer 516 will create trenches that are self-aligned with the underlying back gate regions.

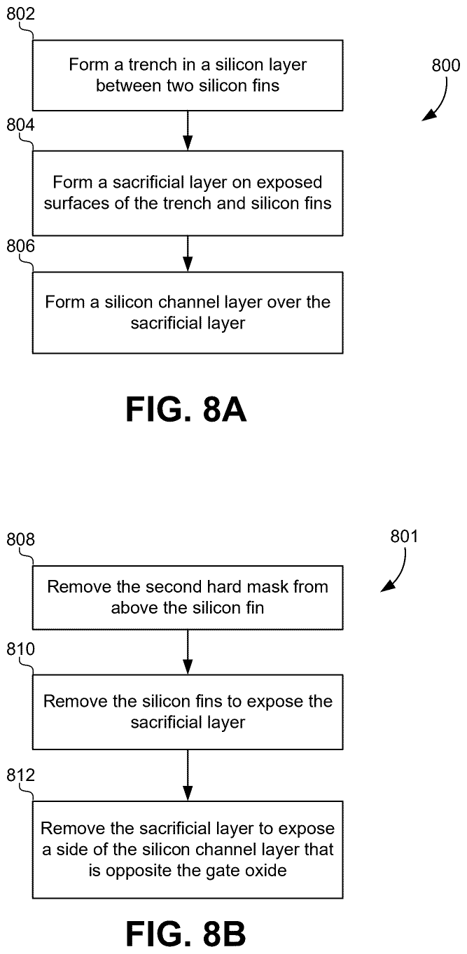

FIGS. 8A-8B illustrate flowcharts of methods 800, 801 of forming portions of a DRAM structure, according to some embodiments. These methods are very similar to the methods 400, 401 illustrated above in FIGS. 4A-4B. However, while the previous embodiments left a silicon nitride hard mask in place such that the subsequent X-cut could be self-aligned, methods 800, 801 illustrate a non-self-aligned technique that allows the hard mask to be removed.

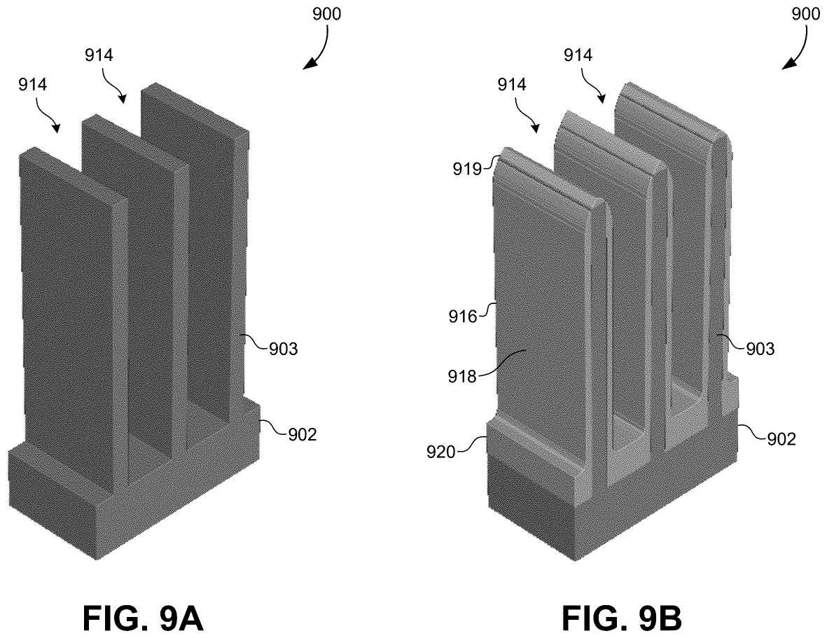

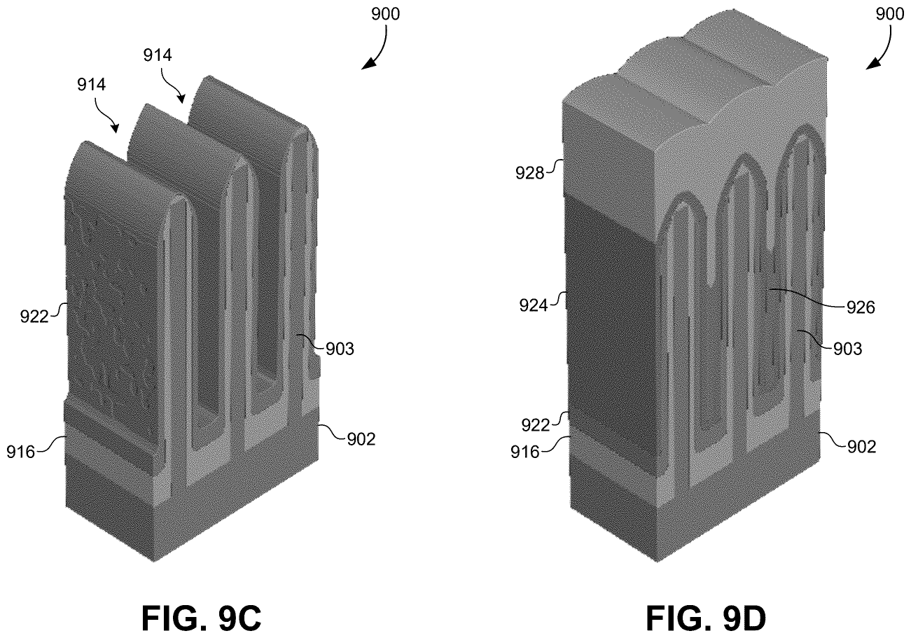

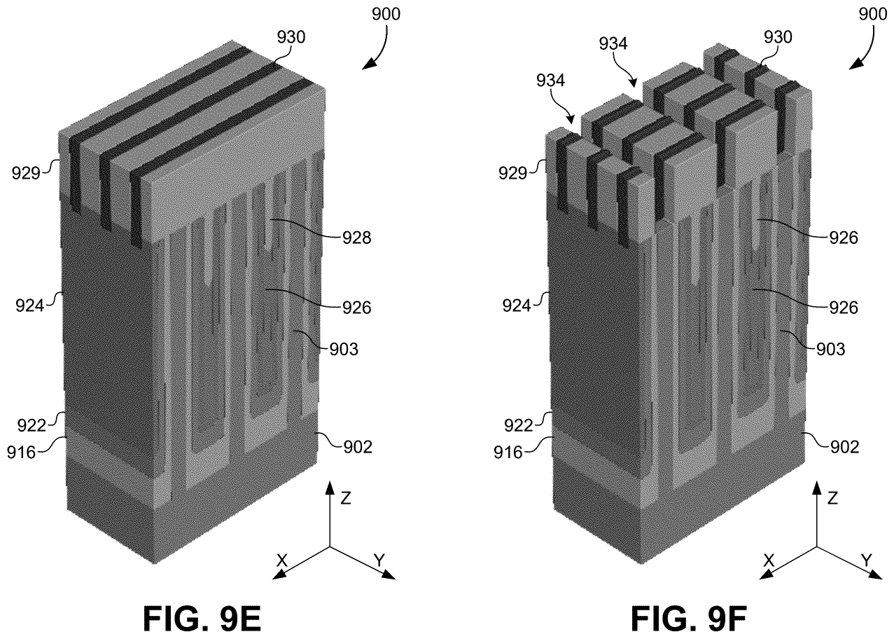

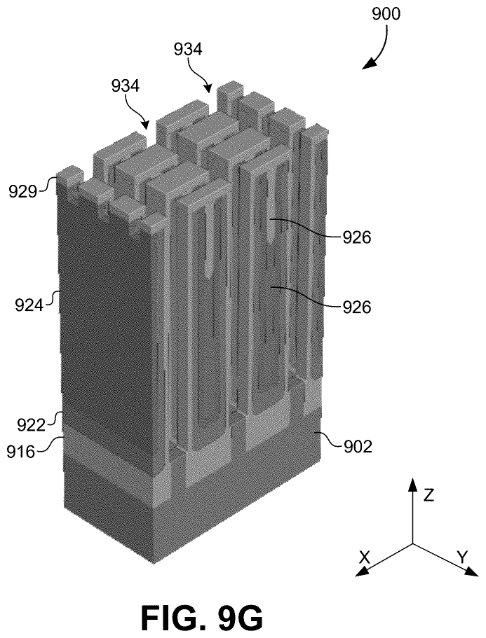

FIGS. 9A-9G illustrate incremental steps for forming a semiconductor structure 900 for a DRAM array using a non-self-aligned technique, according to some embodiments. The incremental structures illustrated in these figures may represent example structures that may be performed by the operations of methods 800, 801. However, the structures are provided only by way of example and are not meant to be limiting. The operations of methods 800, 801 may be broader than these example structures, and additional processes and structures may be included in different embodiments.

Beginning with method 800, a silicon channel layer may be formed by first etching the relatively wide trench in the silicon substrate. The exposed surfaces of the structure may then be conformally coated with a sacrificial layer, such as silicon germanium. In some embodiments, the sacrificial layer may be epitaxially grown on the exposed surfaces. Finally, the silicon channel layer may also be epitaxially grown over the sacrificial layer.

The method 800 may include forming a trench in a silicon layer between two silicon fins (802). FIG. 9A illustrates an initial semiconductor structure for forming a memory array. The process for forming the trenches 914 between the silicon fins 903 on the substrate 902 may be performed substantially as described above for the self-aligned technique. For example, the dimensions and etch techniques described above may be used in this method.

After the trenches 914 are etched between the two silicon fins 903 on the substrate 902, the hard mask used to define the trench pattern may be removed. In contrast to the earlier method described in FIG. 4A, which relied on a hard mask made from silicon nitride (or other similar materials), this method allows greater flexibility in the choice of hard mask material. Specifically, this method does not require the hard mask to remain intact during subsequent processing steps. In the self-aligned method, the silicon nitride hard mask served as a component for self-alignment with subsequent etching steps. This approach required the hard mask to withstand multiple CMP and etching processes, limiting the materials that could be used for the hard mask to those with high durability and selectivity relative to the silicon, silicon germanium, and other materials in the semiconductor structure 900. In contrast, this non-self-aligned method simplifies the process by removing the hard mask after the trenches 914 are defined. This allows the use of softer or easier-to-remove materials, such as silicon oxide, which are also easier to deposit, pattern, and subsequently remove.

The removal of the hard mask may involve a selective etching process that targets the chosen hard mask material without affecting the underlying silicon fins 903 or the silicon substrate 902. For example, if a silicon oxide hard mask is used, a wet etch process using hydrofluoric acid (HF) or a vapor-phase HF process may be applied to remove the oxide. These etching methods are highly selective to oxide and will not adversely impact the silicon fins 903.

The method 800 may also include forming a sacrificial layer on the exposed surfaces of the trench and the silicon fins (804). FIG. 9B illustrates the formation of the sacrificial layer 916 on the exposed surfaces of the semiconductor structure 900, including the trench sidewalls and bottoms, as well as the top surfaces 919 of the silicon fins 903. Unlike the self-aligned method, which required the sacrificial layer to be selectively formed only on the exposed silicon of the trench sidewalls and bottoms, and not on the hard mask, this non-self-aligned method allows for a more generalized deposition process that coats all exposed surfaces uniformly and/or conformally.

The sacrificial layer 916 may be deposited using a non-selective process, such as epitaxial growth, chemical vapor deposition (CVD), or atomic layer deposition (ALD). These techniques enable the sacrificial layer 916 to form over all exposed surfaces of the semiconductor structure 900, including the sidewalls and bottoms of the trenches 914, as well as the top surfaces 919 of the silicon fins 903. In some embodiments, the sacrificial layer 916 may be formed using epitaxial growth. Thus, the sacrificial layer 916 may exhibit different thicknesses depending on the lattice geometry of the underlying silicon as described above. These thickness differences may still be leveraged subsequent processing steps, as the thicker bottom portion 920 may serve as a robust stop layer during substrate removal or other etching processes. In some embodiments, the sacrificial layer 916 may be between about 3 nm or about 20 nm thick. Alternatively, the sacrificial layer may be about 0 nm thick, such that some embodiments may omit the sacrificial layer 916 entirely.

The method 800 may further include forming a silicon channel layer on the over the sacrificial layer (806). FIG. 9C illustrates the formation of a channel layer 922, according to some embodiments. For example, the channel layer 922 may also be grown epitaxially on the sacrificial layer 916. The channel layer 922 may be a silicon channel layer that is grown epitaxially to a predetermined thickness of between about 9 nm and about 13 nm on the sidewall of the underlying sacrificial layer 916. This process generates a high-quality silicon channel layer with a thickness that may be very accurately controlled. Additionally, the thickness of the channel layer 922 may be uniform throughout the height of the channel layer 922 along the sidewalls of the trenches 914 due to the epitaxial growth.

Unlike the self-aligned method, where the presence of the hard mask restricted the deposition of the channel layer to the sidewalls and bottoms of the trenches, the non-self-aligned method allows the channel layer 922 to be formed over all exposed surfaces of the sacrificial layer 916, including the tops of the silicon fins 903. Since the hard mask has already been removed, there is no need for a selective process. While the channel layer 922 and sacrificial layer 916 on top of the silicon fins 903 are not required for the final structure and will later be removed, their formation during this step ensures that the process is more flexible and compatible with a broader range of deposition techniques.

At this stage, the width and geometry of the channel regions have been defined by the epitaxial growth of the channel layer 922. Additional processes may now be performed that form the back gate region inside of the channel layer 922 and prepare the semiconductor structure 900 to remove the silicon fins 903 and expose the channel layer 922. These processes may be performed as described above for the self-aligned method in FIGS. 5E-5F. For example, FIG. 9D illustrates the formation of the back gate region, according to some embodiments. The back gate region may be formed by first depositing a gate oxide 924 over the channel layer 922. This gate oxide 924 may be formed using a conformal deposition process, ensuring a uniform coating along the sidewalls and bottoms of the trenches 914 over the channel layer 922. After forming the gate oxide 924, the remaining area of the trenches 914 may be filled with a back gate metal 926, such as titanium nitride, tungsten, or molybdenum, using a deposition process that minimizes voids and ensures complete filling. Once the trenches are filled, the back gate metal 926 may be recessed to a predetermined depth within the trenches 914. The recessed back gate metal 926 may then be covered with a dielectric 928, such as silicon oxide, which forms a dielectric plug to isolate the back gate region. The dielectric 928 may result in an overburden that extends above the fins and substantially covers the surface of the semiconductor structure 900.

FIG. 9E illustrates a Y-cut in the semiconductor structure 900, according to some embodiments. The overburden of the dielectric 928, which forms a dielectric plug over the back gate metal 926, may be planarized to create a flat surface. This planarization process may be performed using a CMP process or an etch process to form a smooth and level surface. The planarization may expose the tops of the silicon fins 903, the sacrificial layer 916, and the channel layer 922, as well as the top of the gate oxide 924 and the dielectric 928 that forms the dielectric plug.

After planarization, the flat surface may be covered with a second hard mask material 929 to prepare for further processing. The second hard mask material 929 may be made of silicon oxide or other similar materials that provide a protective layer for subsequent etching processes. The second hard mask 929 may be patterned, and a Y-cut may then be made in the semiconductor structure 900 by selectively etching through the second hard mask material 929. The Y-cut trenches may expose the underlying layers and stop at the underlying layers. Alternatively, the Y-cut trenches may extend below the hard mask 929 into the sacrificial layer 916 and channel layer 922 by a depth of between about 1 nm and about 5 nm. The Y-cut process may be performed using a dry plasma-based etch, such as a reactive ion etch (RIE), or a wet etching process tailored to the hard mask.

The Y-cut trenches created in this process may be subsequently filled with a fill material, such as polysilicon 930, to provide isolation. The polysilicon 930 may be deposited into the Y-cut trenches using any deposition process. After deposition, a polishing step, such as a CMP process, may be performed to remove any overburden of the polysilicon 930 and create a smooth, level surface.

After performing the Y-cut, a processing stage may be executed to expose the silicon channel layer that is opposite of the back gate oxide by removing the silicon fins 903 and a portion of the sacrificial layer 916. Turning back to FIG. 8B, the method 801 may be used to form a portion of the DRAM structure by exposing the silicon channel layer. Since this subprocess may be considered separately from other subprocesses when manufacturing a DRAM structure, the method 801 may begin by receiving a semiconductor structure that includes a silicon fin underneath a hard mask; a sacrificial layer on a sidewall of a silicon fin; a silicon channel layer on the sacrificial layer; and a gate oxide on the silicon channel layer.

The method 801 may include removing the hard mask 929 from above the silicon fin (808). FIG. 9F illustrates removing the hard mask 929 above the silicon fins 903, according to some embodiments. As shown, removing this portion of the hard mask 929 may expose the tops of the silicon fins 903 and, in some cases, a portion of the sacrificial layer 916 that covers the silicon fins 903. This process may also be referred to as opening the hard mask 929, and the openings 934 may remove trenches in the hard mask 929 and the polysilicon 930 fill material. Careful control of the hard mask removal process ensures that the channel layers 922, located along the sidewalls of the trenches 914 beneath the sacrificial layer 916, may remain protected and are not exposed during this step. This selective removal is crucial for preserving the integrity of the channel layers 922 and preventing unintended damage or contamination.

In contrast to the self-aligned method described earlier, this non-self-aligned method requires the openings 934 in the hard mask 929 to be precisely aligned with the silicon fins 903. Proper alignment ensures that these openings 934 correspond accurately to the silicon columns and other underlying features. While this introduces an additional alignment requirement compared to the self-aligned method, the sacrificial layer 916 provides an additional margin of error which may simplify the alignment process.

The sacrificial layer 916, which was deposited over the exposed surfaces of the silicon fins 903, may act as a protective buffer during the hard mask removal process. Since the sacrificial layer 916 will eventually be removed in subsequent steps, it provides additional tolerance for minor misalignment in the hard mask openings 934. Small deviations in the alignment of the hard mask 929 pattern with the underlying silicon fins 903 are less critical because the sacrificial layer 916 can compensate for these errors without compromising the underlying channel layers 922. This margin of error reduces the risk of defects and ensures that the final structure is robust and well-formed, even in cases where the alignment is not perfectly precise.

The method 801 may also include removing the silicon fins to expose the sacrificial layer (810). FIG. 9G illustrates the removal of the silicon fins, according to some embodiments. The etch may be configured to remove the optional fill material 930 (e.g., polysilicon) and at least a portion of the silicon fins 903 of the silicon substrate 902. For example, the etch may be selective to silicon and the fill material 930, while not being selective to the silicon germanium of the sacrificial layer 916. The etch may be timed such that the silicon fins 903 may be removed down to a predetermined depth. For example, the silicon fins 903 may be removed to a level that is just above the bottom of the back gate metal 926 as illustrated in FIG. 9G. Although not clearly visible in FIG. 9G, any exposed silicon in the Y direction may also be removed since this silicon would not be protected by any overlying layers. After the X and Y cuts are made in the semiconductor structure 900, the individual devices will be cut into separate pillars as illustrated in FIG. 9G.

Depending on the controllability and precision of the etch process, some residual silicon from the silicon fins of the silicon substrate 902 may remain on the sidewalls of the sacrificial layer 916. The majority of the silicon may be removed by the etch, and any remaining silicon on the sacrificial layer 916 will typically be oxidized. Therefore, some embodiments may perform an optional process of using a selective etch (selectivity to the sacrificial liner, such as silicon germanium) that removes any remaining oxidized silicon and silicon pillar on the sidewalls of the Y trenches 934. This selective etch may not affect the silicon at the bottom of the Y trenches 934 or the sacrificial layer 916 (e.g., silicon germanium). This may fully expose the sacrificial layer 916 on the sidewalls of the Y trenches 934.

The method 801 may further include removing the sacrificial layer to expose a side of the silicon channel layer that is opposite the gate oxide (812). As described above, an etch process maybe use that is selective to the specific material used for the sacrificial layer 916. For example, when silicon germanium is used, a dry plasma-based etch (e.g., HBr) or an atomic layer etch (Cl₂-based) may be used to selectively remove silicon germanium without damaging the silicon or other materials in the semiconductor structure 900. Removing the sacrificial layer 916 from the sidewalls exposes the silicon of the channels 922. In some embodiments, this etch process may be a timed etch rather than an exhume etch. The timing of the etch may be controlled to remove the sacrificial layer 916 from the sidewalls of the Y trenches 934 without significantly recessing the sacrificial layer 916 from the bottom of the Y trenches 934. As illustrated in FIG. 9J, the sacrificial layer 916 at the bottom of the Y trenches 934 may form cup-shaped regions that are useful for providing a self-aligned feature for backside processing as described below. Note that some recessing may be tolerated in order to remove all of the sacrificial layer 916 from the sidewalls of the trenches 934.

At this stage, the semiconductor structure 900 may be process as described above to complete the DRAM structure. Therefore, both the self-aligned methods of FIGS. 4A-4B and the non-self-aligned methods of FIGS. 8A-8B may yield similar structures at this point.

As used herein, the terms “about” or “approximately” or “substantially” may be interpreted as being within a range that would be expected by one having ordinary skill in the art in light of the specification. By way of example, these terms may imply a 10% variation above or below a stated value (i.e., “approximately 50” would imply a range between 45 and 55).

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of forming a portion of a DRAM structure, the method comprising:
forming a trench in a silicon layer between two silicon fins;
forming a sacrificial layer on sidewalls of the trench between the two silicon fins; and
forming a silicon channel layer on the sidewalls of the trench over the sacrificial layer.

2. The method of claim 1, further comprising:
forming a gate region in the trench within the silicon channel layer such that the silicon channel layer is adjacent to a gate oxide of the gate region;
removing the two silicon fins around the trench; and
removing the sacrificial layer to expose a side of the silicon channel layer that is opposite the gate oxide.

3. The method of claim 1, wherein a pitch of the trench is sufficient for a main gate region and a back gate region of a transistor.

4. The method of claim 1, wherein:
widths of each of the two silicon fins is between about 10 nm and about 25 nm;
a width of the trench is between about 30 nm and about 60 nm;
a width of the sacrificial layer is between about 0 nm and about 20 nm; and
a width of the silicon channel layer is between about 3 nm and about 13 nm.

5. The method of claim 1, wherein:
forming the sacrificial layer comprises epitaxially growing the sacrificial layer on the sidewalls of the trench; and
forming the silicon channel layer comprises epitaxially growing the silicon channel layer on the sacrificial layer.

6. The method of claim 1, further comprising forming the sacrificial layer on a bottom of the trench, wherein the sacrificial layer comprises silicon germanium, and a height of the sacrificial layer on the bottom of the trench is greater than a width of the sacrificial layer on the sidewalls of the trench.

7. The method of claim 6, wherein a germanium concentration in the sacrificial layer on the bottom of the trench is different than a germanium concentration in the sacrificial layer on the sidewalls of the trench.

8. A method of forming a portion of a DRAM structure, the method comprising:
receiving a semiconductor structure comprising:
a silicon fin underneath a hard mask;
a sacrificial layer on a sidewall of the silicon fin;
a silicon channel layer on the sacrificial layer; and
a gate oxide on the silicon channel layer;
removing the hard mask from above the silicon fin;
removing the silicon fin to expose the sacrificial layer; and
removing the sacrificial layer to expose a side of the silicon channel layer that is opposite the gate oxide.

9. The method of claim 8, further comprising forming the gate oxide as a conformal layer on the silicon channel layer, and annealing the semiconductor structure at a temperature less than 1000 °C such that germanium in the sacrificial layer does not defuse into the silicon channel layer.

10. The method of claim 8, further comprising performing a chemical mechanical polishing (CMP) process to expose the silicon fin, wherein the CMP process stops before exposing the silicon channel layer.

11. The method of claim 8, further comprising performing a Y-cut on the semiconductor structure before removing the silicon fin to expose the sacrificial layer.

12. The method of claim 8, further comprising:
filling a region left after removing the hard mask with polysilicon; and
removing the silicon fin by etching the polysilicon and the silicon fin in a single process.

13. The method of claim 8, wherein removing the silicon fin is a self-aligned process to create a main gate region adjacent to a back gate region.

14. The method of claim 8, further comprising removing a layer of residual silicon from the sacrificial layer before removing the sacrificial layer.

15. A method of forming a portion of a DRAM structure, the method comprising:
receiving a semiconductor structure comprising:
capacitors for DRAM cells on a top side of the silicon structure;
back gate regions for the DRAM cells underneath the capacitors in the silicon structure, wherein the back gate regions comprise sacrificial layers beneath the back gate regions; and
a substrate on a bottom of the silicon structure and beneath the back gate regions; and
removing a portion of the substrate beneath the sacrificial layers, wherein the sacrificial layers act as stop layers for a removal process.

16. The method of claim 15, further comprising, after removing the portion of the substrate beneath the sacrificial layers, removing a remaining portion of the substrate between the sacrificial layers.

17. The method of claim 16, further comprising performing a main gate recess and a main gate fill with silicon nitride between the sacrificial layers after removing the remaining portion of the substrate between the sacrificial layers.

18. The method of claim 16, wherein removing the remaining portion of the substrate between the sacrificial layers is a self-aligned process for exposing main gate regions.

19. The method of claim 15, wherein the sacrificial layers comprise epitaxial silicon germanium.

20. The method of claim 15, wherein the sacrificial layers comprise cup-shaped regions of material formed at bottoms of trenches for back gate regions, and the sacrificial layers are not connected to each other.
